(19) United States
(12) Patent Application Publication
(10) Pub. No.: US 2017/0256571 A1
(43) Pub. Date: Sep. 7, 2017

(54) Sharing Capacitor, Pixel Having Sharing Capacitor, And Array Substrate Having Sharing Capacitor

(71) Applicant: Shenzhen China Star Optoelectronics Technology Co., Ltd., Shenzhen, Guangdong (CN)

(72) Inventor: Huan LIU, Shenzhen, Guangdong (CN)

(73) Assignee: Shenzhen China Star Optoelectronics Technology Co., Ltd., Shenzhen, Guangdong (CN)

(21) Appl. No.: 14/898,226

(22) PCT Filed: Nov. 6, 2015
(86) PCT No.: PCT/CN2015/094035

§ 371 Date: Dec. 14, 2015

(30) Foreign Application Priority Data
Nov. 2, 2015 (CN) 201510730916.7

(51) Int. Cl. H01L 27/12; H01L 23/522; H01L 23/532; H01L 49/02

(52) U.S. Cl. CPC H01L 27/1255; H01L 28/60; H01L 23/5226; H01L 23/5329; H01L 27/1218; G02F 2201/40; G02F 1/1362

(57) ABSTRACT

The present invention proposes a sharing capacitor, a pixel having the sharing capacitor, and an array substrate having the sharing capacitor. The sharing capacitor includes a first electrode layer, a first dielectric layer, disposed on the first electrode layer, a second electrode layer disposed on the first dielectric layer and separated from the first electrode layer by the first dielectric layer, a second dielectric layer disposed on the second electrode layer, and a third electrode layer disposed on the second dielectric layer and separated from the second electrode layer by the second dielectric layer. The third electrode layer is electrically connected to the first electrode layer. The sharing capacitor and the pixel having the sharing capacitor according to the present invention are capable of increasing an aperture ratio of a pixel, and upgrading display quality of the liquid crystal display.

### BACKGROUND OF THE INVENTION

1. Field of the Invention

The present invention relates to a thin film transistor liquid crystal display, more particularly, to a sharing capacitor, a pixel having the sharing capacitor, and an array substrate having the sharing capacitor.

2. Description of the Prior Art

In a thin film transistor liquid crystal display (TFT-LCD) using vertical alignment (VA) technology, a pixel is divided into a main area and a sub area. Alignment of the liquid crystals in the sub area is different from that in the main area, because pixel voltage applied on the sub area is lower than that applied on the main area, so to improve color shift of viewing in wide viewing angle.

A charge-sharing technique is usually used to make pixel voltage of the sub area lower than pixel voltage of the main area. FIG. 1 shows a conventional pixel adopting the charge-sharing technique. The pixel is divided into a main area and a sub area. The pixel comprises a main thin film transistor 2, a secondary thin film transistor 3, a charging gate line 4, a sharing gate line 5, and a sharing thin film transistor 6. The pixel electrodes ITO of the main area and sub area are charged when the charging gate line 4 turns on. Afterwards, the charging gate line 4 turns off and the sharing gate line 5 turns on, so that the sharing capacitor 1 conducts to the pixel electrode ITO of the sub area to share part of charge applied on the pixel electrode. Therefore, the voltage on the pixel electrode of the sub area lowers to make different voltages applied on the sub area and the main area.

The conventional sharing capacitors are mainly divided into two structures: one is MII structure and the other is MIS structure.

Refer to FIG. 2 and FIG. 3. FIG. 2 shows a cross sectional view of a conventional MII structure sharing capacitor, and FIG. 3 shows an equivalent circuit diagram of the sharing capacitor of FIG. 2. The sharing capacitor 100 comprises a first metal layer 101 on an array substrate 110, a first dielectric layer 102, a second dielectric layer 103, and a pixel electrode layer 104 made of Indium Tin Oxide (ITO). The first metal layer 101 and the pixel electrode layer 104 are served as two electrode plates of the sharing capacitor 100. As shown in FIG. 3, the first metal layer 101 connects to voltage level V_{COM}. Because the pixel electrode layer 104 connects to the second metal layer 105 through the via hole 106, charge in the sub area of the pixel is shared to the pixel electrode layer 104 through the sharing TFT 6 (see FIG. 1), so that the pixel electrode layer 104 is applied with voltage level V_{SH}.

Refer to FIG. 4 and FIG. 5. FIG. 4 shows a cross sectional view of a conventional MIS structure sharing capacitor, and FIG. 5 shows an equivalent circuit diagram of the sharing capacitor of FIG. 4. The sharing capacitor 200 comprises a first metal layer 201 on an array substrate 210, a first dielectric layer 202, and a second metal layer 203. Furthermore, a second dielectric layer 220 is disposed on the second metal layer 203. The first metal layer 201 and the second metal layer 203 are served as two electrode plates of the sharing capacitor 200. As shown in FIG. 5, the first metal layer 101 connects to voltage level V_{COM}. The second metal layer 203 is connected with the sharing TFT 6 (see FIG. 1), so that the second metal layer 203 is applied with voltage level V_{SH}.

Nevertheless, existence of the sharing capacitor decreases an aperture ratio of the pixel. Also, the bigger the area of the electrode plate of the sharing capacitor is, the less the aperture ratio of the pixel is.

Although shrinking the area of the electrode plate without reducing the capacitance is a way to raising the aperture ratio of the pixel, how to lower the voltage applied in the sub area by adjusting the capacitance of the sharing capacitor to share the amount of charge Q is considered. The shared amount of charge Q is expressed by Formula 1:

Q=C·V, (Formula 1)

where C indicates a capacitance of the sharing capacitor, and V is a voltage across the two electrode plates of the sharing capacitor. Since the value of V is a constant for each fixed grey level voltage, the capacitance of the sharing capacitor is properly adjusted to improve display quality of viewing in a large viewing angle. The capacitance of the sharing capacitor is expressed as:

$$C = \frac{ɛ A}{d} , \qquad ( Formula 2 )$$

where ∈ indicates a permittivity, A indicates to an area of the electrode plate, d indicates to a distance between the two electrode plates.

Although shrinking the area of the electrode plate can increase the aperture ratio of the pixel, the capacitance of the sharing capacitor lowers as well, and fails to share sufficient charge.

### SUMMARY OF THE INVENTION

Accordingly, the present invention provides a sharing capacitor, a pixel having the sharing capacitor, and an array substrate having the sharing capacitor to remedy the problem in the prior art.

According to the present invention, a sharing capacitor comprises a first electrode layer, a first dielectric layer, disposed on the first electrode layer, a second electrode layer disposed on the first dielectric layer and separated from the first electrode layer by the first dielectric layer, a second dielectric layer disposed on the second electrode layer, and a third electrode layer disposed on the second dielectric layer and separated from the second electrode layer by the second dielectric layer. The third electrode layer is electrically connected to the first electrode layer.

In one aspect of the present invention, the sharing capacitor further comprises a via hole defined over the first electrode layer. The third electrode layer electrically connects to the first electrode through the via hole.

In another aspect of the present invention, the via hole is formed through the first dielectric layer and/or the second dielectric layer.

In another aspect of the present invention, the first dielectric layer is made of silicon nitride (SiNx).

In still another aspect of the present invention, the second dielectric layer is made of silicon nitride (SiNx).

In yet another aspect of the present invention, the third electrode layer is made of Indium Tin Oxide (ITO).

According to the present invention, a pixel comprises a sharing capacitor. The sharing capacitor comprises a first electrode layer, a first dielectric layer, disposed on the first electrode layer, a second electrode layer disposed on the first dielectric layer and separated from the first electrode layer by the first dielectric layer, a second dielectric layer disposed on the second electrode layer, and a third electrode layer disposed on the second dielectric layer and separated from the second electrode layer by the second dielectric layer. The third electrode layer is electrically connected to the first electrode layer.

In one aspect of the present invention, the pixel further comprises a main area and a sub area. The main area is electrically connected to the sub area, so that pixel voltage applied in the sub area is lower than that applied in the main area.

According to the present invention, an array substrate comprises a sharing capacitor. The sharing capacitor comprises a first electrode layer, a first dielectric layer, disposed on the first electrode layer, a second electrode layer disposed on the first dielectric layer and separated from the first electrode layer by the first dielectric layer, a second dielectric layer disposed on the second electrode layer, and a third electrode layer disposed on the second dielectric layer and separated from the second electrode layer by the second dielectric layer. The third electrode layer is electrically connected to the first electrode layer.

In one aspect of the present invention, the array substrate is a glass substrate.

In contrast to the prior art, the sharing capacitor and the pixel having the sharing capacitor according to the present invention are capable of increasing an aperture ratio of a pixel, and upgrading display quality of the liquid crystal display.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a conventional pixel adopting the charge-sharing technique.

FIG. 2 shows a cross sectional view of a conventional MII structure sharing capacitor.

FIG. 3 shows an equivalent circuit diagram of the sharing capacitor of FIG. 2.

FIG. 4 shows a cross sectional view of a conventional MIS structure sharing capacitor.

FIG. 5 shows an equivalent circuit diagram of the sharing capacitor of FIG. 4.

FIG. 6 shows a cross-sectional view of a sharing capacitor according to a preferred embodiment of the present invention.

FIG. 7 is a circuit diagram of the sharing capacitor as shown in FIG. 6.

### DETAILED DESCRIPTION OF THE PREFERRED EMBODIMENTS

Although the present invention has been explained by the embodiments shown in the drawings described above, it should be understood to the ordinary skilled person in the art that the invention is not limited to the embodiments, but rather various changes or modifications thereof are possible without departing from the spirit of the invention.

It should be understood that, when an element or layer is referred to herein as being “disposed on”, “connected to” or “coupled to” another element or layer, it can be directly disposed on, connected or coupled to the other element or layer, or alternatively, that intervening elements or layers may be present. In contrast, when an element is referred to as being “directly disposed on,” “directly connected to” or “directly coupled to” another element or layer, there are no intervening elements or layers present. In the figures, like numbers refer to like elements throughout. As used herein, the term “and/or” includes any and all combinations of one or more of the associated listed items.

It should further be understood that, although the terms first, second, third, and the like may be used herein to describe various elements, components, regions, layers and/or sections, these elements, components, regions, layers and/or sections should not be limited by these terms. These terms are used only to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The sharing capacitor comprises: a first electrode layer; a first dielectric layer, disposed on the first electrode layer; a second electrode layer, disposed on the first dielectric layer and separated from the first electrode layer by the first dielectric layer; a second dielectric layer, disposed on the second electrode layer; a third electrode layer, disposed on the second dielectric layer and separated from the second electrode layer by the second dielectric layer. The third electrode layer is electrically connected to the first electrode layer.

The sharing capacitor according to the present invention keeps a capacitance with a smaller area of the electrode plates, so as to increase aperture ratio of a pixel.

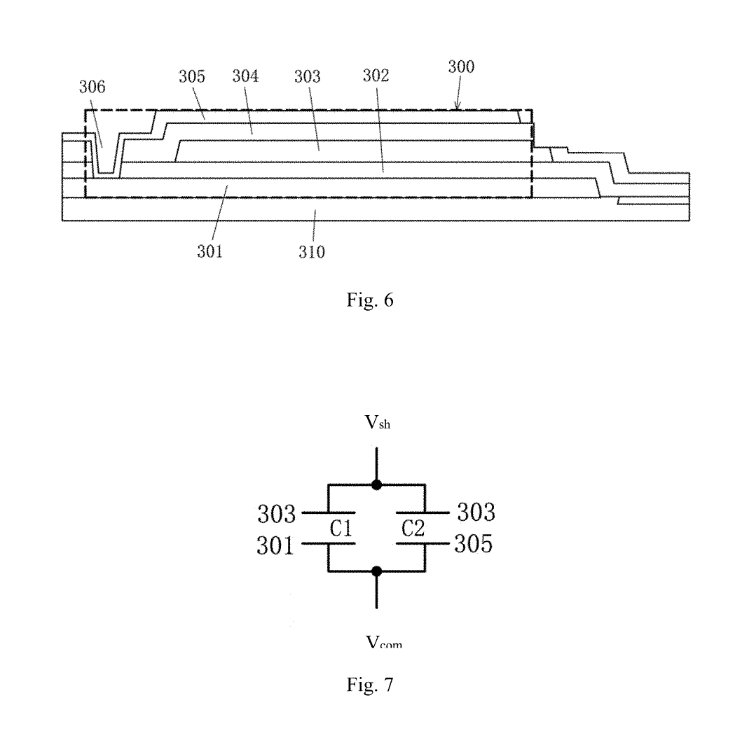

FIG. 6 shows a cross-sectional view of a sharing capacitor 300 according to a preferred embodiment of the present invention. FIG. 7 is a circuit diagram of the sharing capacitor 300 as shown in FIG. 6. As shown in FIG. 6, the sharing capacitor 300 comprises a first electrode layer 301 disposed on an array substrate 310, a first dielectric layer 302 disposed on the first electrode layer 301, a second electrode layer 303 disposed on the first dielectric layer 302, a second dielectric layer 304 disposed on the second electrode layer 303, and a third electrode layer 305 disposed on the second dielectric layer 304. The second electrode layer 303 and the first electrode layer 301 are separated by the first dielectric layer 302, and the third electrode layer 305 and the second electrode layer 303 are separated by the second dielectric layer 304. The third electrode layer 305 electrically connected to the first electrode layer 301 through a via hole 306.

The array substrate 310 may be but is not limited to a glass substrate. In the present invention, the via hole 306 penetrates through the first dielectric layer 302 and second dielectric layer 304, so that the first electrode layer 301 connects the third electrode layer 305. The via hole 306 is used to electrically connect the third electrode layer 305 and the first electrode layer 301 and is not limited to its shape and position on the premise of the third electrode layer 305 isolation from the second electrode layer 303.

Preferably, the first dielectric layer 302 and second dielectric layer 304 can be made of silicon nitride (SiNx). The third electrode layer 305 is used as a pixel electrode and is made of Indium Tin Oxide (ITO).

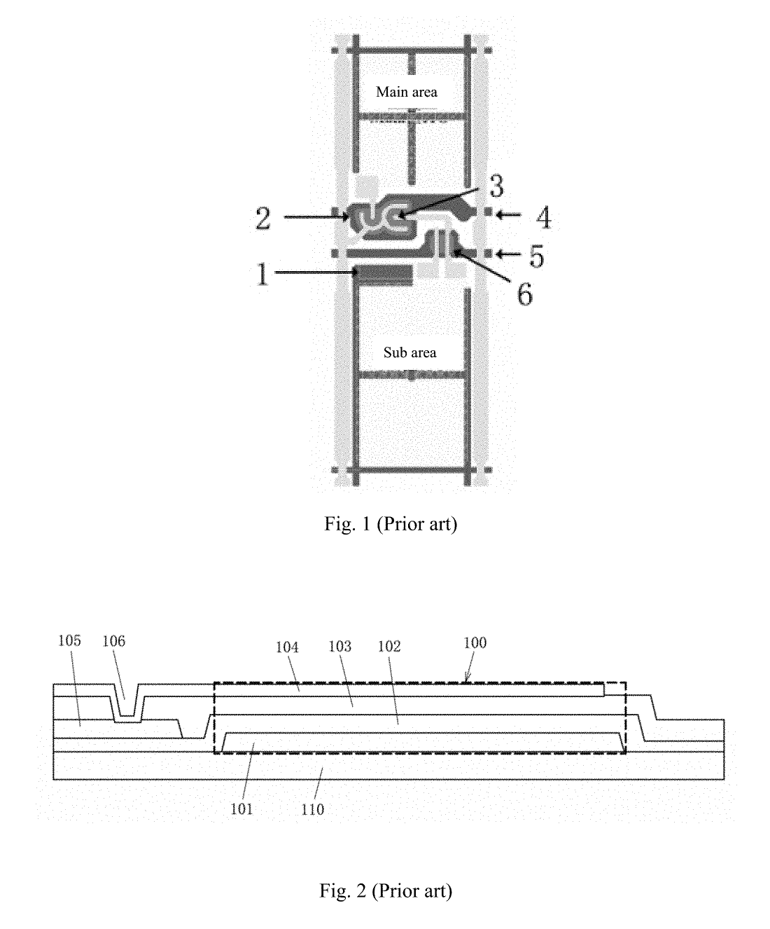

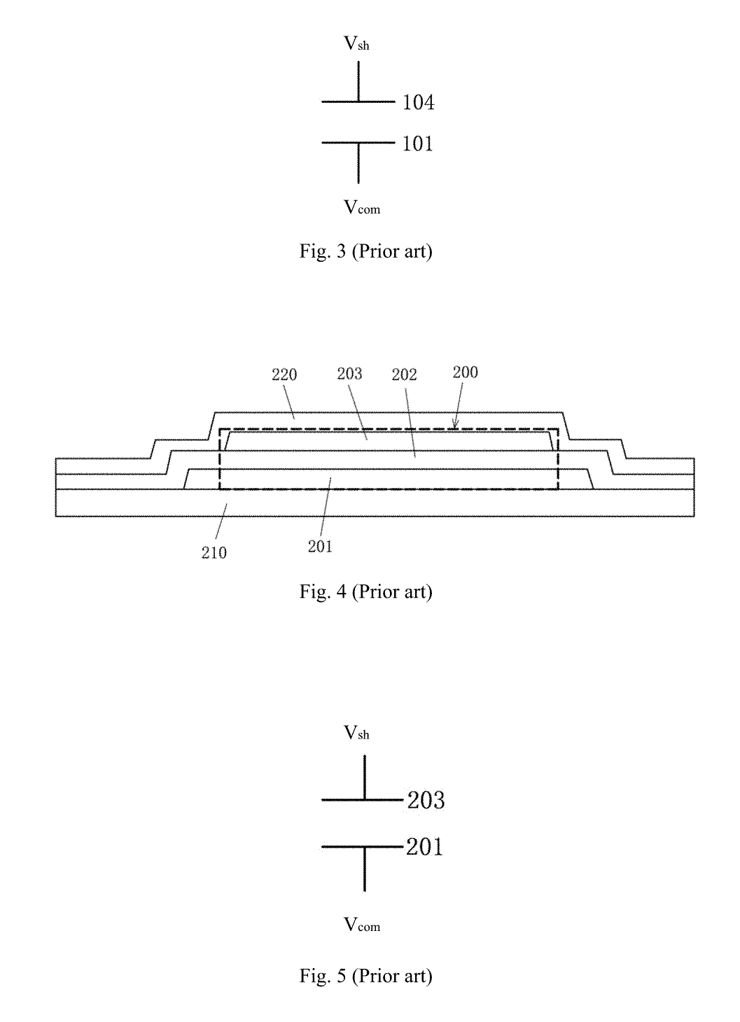

As shown in FIG. 6, differing from the conventional sharing capacitor, the sharing capacitor according to the present embodiment adopts a three-layer structure, i.e. the first electrode layer 301 (Metal 1)∥ the second electrode layer 303 (Metal 2)∥ the third electrode layer 305 (ITO). The third electrode layer 306 connects to the first electrode layer 301 through the via hole 306. As shown in FIG. 7, both the third electrode layer 305 and first electrode layer 301 connect to a voltage level V_{COM}. The second electrode layer 303 connects to the sharing TFT 6 (see FIG. 1), so that the sharing TFT 6 keeps the voltage level V_{SH}. The laminated-layer capacitor with a smaller area of the electrode plate can raise an aperture ratio of a pixel, thereby upgrading transmittance and display quality of the LCD.

The present invention also proposes a pixel using the sharing capacitor therein. Since the pixel of the present invention is similar to the convention pixel shown in FIG. 1 except the sharing capacitor, the detailed description about the present inventive pixel is omitted.

As mentioned above, the sharing capacitor adopts three layers with the first electrode layer 301 (Metal 1)∥ the second electrode layer 303 (Metal 2)∥ the third electrode layer 305 (ITO). The first electrode layer 301 and the second electrode layer 303 form a sub capacitor C1. The second electrode layer 303 and the third electrode layer 305 form a sub capacitor C2 which is connected with the sub capacitor C1 in series. Therefore, the capacitance C of the sharing capacitor 300 equals to C1+C2. Under the same electrode plate, C is greater than C1 or C2. In contrast to the conventional sharing capacitor, the sharing capacitor according to the present invention utilizes a smaller electrode plate in area, thereby increasing an aperture ratio of a pixel, and upgrading display quality of the liquid crystal display. In addition, the present invention is easy to be realized by using the conventional manufacturing processes, no more processes are needed.

In conclusion, the sharing capacitor and the pixel having the sharing capacitor according to the present invention are capable of increasing an aperture ratio of a pixel, and upgrading display quality of the liquid crystal display.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

What is claimed is:

1. A sharing capacitor, comprising:
a first electrode layer;
a first dielectric layer, disposed on the first electrode layer;
a second electrode layer, disposed on the first dielectric layer and separated from the first electrode layer by the first dielectric layer;
a second dielectric layer, disposed on the second electrode layer;
a third electrode layer, disposed on the second dielectric layer and separated from the second electrode layer by the second dielectric layer;
wherein the third electrode layer is electrically connected to the first electrode layer.

2. The sharing capacitor as claimed in claim 1, further comprising: a via hole defined over the first electrode layer, wherein the third electrode layer electrically connects to the first electrode through the via hole.

3. The sharing capacitor as claimed in claim 1, wherein the via hole is formed through the first dielectric layer and/or the second dielectric layer.

4. The sharing capacitor as claimed in claim 1, wherein the first dielectric layer is made of silicon nitride (SiNx).

5. The sharing capacitor as claimed in claim 1, wherein the second dielectric layer is made of silicon nitride (SiNx).

6. The sharing capacitor as claimed in claim 1, wherein the third electrode layer is made of Indium Tin Oxide (ITO).

7. A pixel comprising a sharing capacitor, the sharing capacitor comprising:
a first electrode layer;
a first dielectric layer, disposed on the first electrode layer;
a second electrode layer, disposed on the first dielectric layer and separated from the first electrode layer by the first dielectric layer;
a second dielectric layer, disposed on the second electrode layer;
a third electrode layer, disposed on the second dielectric layer and separated from the second electrode layer by the second dielectric layer;
wherein the third electrode layer is electrically connected to the first electrode layer.

8. The pixel as claimed in claim 7 further comprising a main area and a sub area, wherein the main area is electrically connected to the sub area, so that pixel voltage applied in the sub area is lower than that applied in the main area.

9. An array substrate comprising a sharing capacitor, the sharing capacitor comprising:
a first electrode layer;
a first dielectric layer, disposed on the first electrode layer;
a second electrode layer, disposed on the first dielectric layer and separated from the first electrode layer by the first dielectric layer;
a second dielectric layer, disposed on the second electrode layer;
a third electrode layer, disposed on the second dielectric layer and separated from the second electrode layer by the second dielectric layer;
wherein the third electrode layer is electrically connected to the first electrode layer.

10. The array substrate as claimed in claim 9, wherein the array substrate is a glass substrate.
